(19) United States
(12) Patent Application Publication
(10) Pub. No.: US 2025/0369813 A1
(43) Pub. Date: Dec. 4, 2025

(54) TACTILE SENSOR

(71) Applicant: SINTOKOGIO, LTD., Nagoya-shi (JP)

(72) Inventors: Yoshikane TANAAMI, Nagoya-shi (JP); Miyuki HAYASHI, Nagoya-shi (JP)

(73) Assignee: SINTOKOGIO, LTD., Nagoya-shi (JP)

(21) Appl. No.: 19/176,232

(22) Filed: Apr. 11, 2025

(30) Foreign Application Priority Data
May 30, 2024 (JP) 2024-087884

(51) Int. Cl. G01L 5/106; H05K 5/06

(52) U.S. Cl. CPC G01L 5/106; H05K 5/061

(57) ABSTRACT

A tactile sensor includes: a strain layer including a ring part and a tongue part protruding inward from the ring part, the tongue part being provided with a strain gauge; a first sealing layer stacked on one main surface of the strain layer to seal a first space surrounded by the ring part of the strain layer; a spacer layer including a ring part; and a second sealing layer stacked on one main surface of the spacer layer to seal a second space surrounded by the ring part of the spacer layer, the strain layer and the spacer layer being stacked so that the other main surface of the strain layer faces the other main surface of the spacer layer, and a closed space in which the first space and the second space communicate is formed.

This Nonprovisional application claims priority under 35 U.S.C. § 119 on Patent Application No. 2024-087884 filed in Japan on May 30, 2024, the entire contents of which are hereby incorporated by reference.

### TECHNICAL FIELD

The present invention relates to a tactile sensor.

### BACKGROUND ART

Conventionally, tactile sensors having various shapes have been proposed. For example, Patent Literature 1 discloses a force measurement system including a housing body and one or more force sensors. The housing body includes a plurality of surface regions configured to receive a force applied, and at least two individual surface regions of the surface regions are configured to move with respect to each other in response to the application of the force. The force sensors are each configured to generate an output signal indicating information on the force. Further, Patent Literature 1 also discloses making up the force sensor from a load cell into which a strain gauge is incorporated and configuring the load cell as a W-type load cell including a strain gauge disposed at the center.

### CITATION LIST

### Patent Literature

### [Patent Literature 1]

Japanese Patent Application Publication Tokukai No. 2022-126676

### SUMMARY OF INVENTION

### Technical Problem

However, in a case where a conventional tactile sensor as disclosed in Patent Literature 1 is used in an environment where water or dust is present in the surrounding area, the water or dust may penetrate into a housing of the tactile sensor. The water or dust that has penetrated into the housing may adhere to the load cell, resulting in reduction in sensitivity of stress detection of the load cell.

An aspect of the present invention has been implemented in light of the foregoing issue, and it is an object thereof to prevent water and dust from penetrating into a tactile sensor, even if the tactile sensor is used under an environment where water or dust is present in the surrounding area.

### Solution to Problem

In order to attain the foregoing object, a tactile sensor in accordance with an aspect of the present invention includes: a strain layer including a ring part and a tongue part protruding inward from the ring part, the tongue part being provided with a strain gauge; a first sealing layer stacked on one main surface of the strain layer so as to seal a first space surrounded by the ring part of the strain layer; a spacer layer including a ring part; and a second sealing layer stacked on one main surface of the spacer layer so as to seal a second space surrounded by the ring part of the spacer layer, the strain layer and the spacer layer being stacked so that another main surface of the strain layer and another main surface of the spacer layer face each other, and a closed space in which the first space and the second space communicate with each other is formed.

### Advantageous Effects of Invention

Each aspect of the present invention makes it possible to prevent water and dust from penetrating into a tactile sensor, even if the tactile sensor is used under an environment where water or dust is present in the surrounding area.

### BRIEF DESCRIPTION OF DRAWINGS

FIG. 1 is a longitudinal cross-sectional view illustrating one example of a tactile sensor in accordance with Embodiment 1 of an aspect of the present invention.

FIG. 2 is a plan view illustrating one example of the layers constituting the tactile sensor.

FIG. 3 is a longitudinal cross-sectional view illustrating one example tactile sensor in accordance with Embodiment 2 of an aspect of the present invention.

FIG. 4 is a plan view illustrating one example of some of the layers constituting the tactile sensor.

FIG. 5 is a flowchart illustrating one example of a flow of a method for producing a tactile sensor in accordance with an embodiment of another aspect of the present invention.

### DESCRIPTION OF EMBODIMENTS

### <Embodiment 1 of Tactile Sensor>

The following description will discuss Embodiment 1 of the present invention in details with reference to the drawings.

### [Configuration of Tactile Sensor 1]

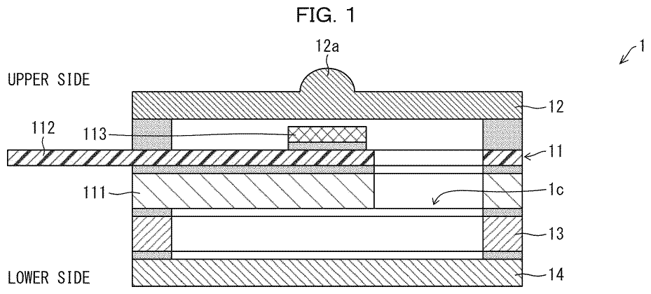

A tactile sensor 1 is provided on, for example, a fingertip of a robot hand. As illustrated in FIG. 1, the tactile sensor 1 includes a strain layer 11, a first sealing layer 12, a spacer layer 13, and a second sealing layer 14. The following description assumes that as viewed from the center of the tactile sensor 1, a side in which the first sealing layer 12 is present is an upper side, and a side in which the second sealing layer 14 is present is a lower side.

### (Strain Layer 11)

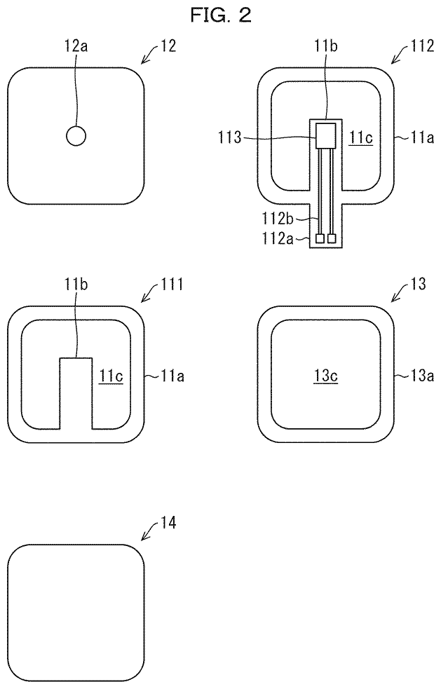

The strain layer 11 in accordance with the present embodiment includes a strain element 111, a film substrate 112, and a strain gauge 113. As illustrated at the middle left of FIG. 2, the strain element 111 includes a portion constituting a ring part 11a and a portion constituting a tongue part 11b in the strain layer 11. The ring part 11a is a portion having a ring shape as viewed from a direction in which the layers are stacked. The tongue part 11b is a portion protruding inward (protruding in a direction in which the center of the ring shaped by the ring part 11a is present) from the ring part 11a. The tongue part 11b in accordance with the present embodiment protrudes to a center part of the strain layer 11. The strain element 111 in accordance with the present embodiment is made of, for example, resin (such as engineering plastic) or metal. The thickness of the strain element 111 in accordance with the present embodiment is not more than 0.5 mm. This enables the strain element 111 to be elastically deformed in a thickness direction of the strain element 111.

As illustrated in FIG. 1, the film substrate 112 in accordance with the present embodiment is stacked on the upper main surface of the strain element 111. Note that the film substrate 112 may be stacked on the lower main surface of the strain element 111. The film substrate 112 in accordance with the present embodiment is bonded to an upper main surface of the strain element 111 with use of an adhesive tape. Note that the film substrate 112 may be stacked with use of a means other than an adhesive tape (for example, with use of an adhesive or a physical fixing tool). As illustrated at the upper right of FIG. 2, the film substrate 112 includes a portion constituting the ring part 11a, a portion constituting the tongue part 11b, a second tongue part 112a, and a wire 112b in the strain layer 11. The second tongue part 112a protrudes outward (protrudes in a direction opposite to the direction in which the tongue part 11b protrudes) from a part serving as a base end of the portion constituting the tongue part 11b in the portion constituting the ring part 11a. The wire 112b extends from a portion constituting the tongue part 11b to the second tongue part 112a. The film substrate 112 in accordance with the present embodiment is made of, for example, a poly ethylene terephthalate (PET) resin. The film substrate 112 configured as above is stacked on the strain element 111, so that the strain layer 11 includes the ring part 11a and the tongue part 11b.

The strain gauge 113 is provided on the tongue part 11b. The strain gauge 113 in accordance with the present embodiment is provided on the upper surface of the portion constituting the tongue part 11b in the film substrate 112. In a case where the film substrate 112 is stacked on the lower main surface of the strain element 111, the strain gauge 113 is provided on the lower surface of the film substrate. The output from the strain gauge 113 is delivered via the wire 112b of the film substrate 112.

### (First Sealing Layer 12)

As illustrated in FIG. 1, the first sealing layer 12 is stacked on an upper main surface (one main surface) of the strain layer 11. The first sealing layer 12 seals a first space 11c (see the upper right and the middle left of FIG. 2) surrounded by the ring part 11a of the strain layer 11. The first sealing layer 12 in accordance with the present embodiment is bonded to the upper main surface of the strain layer 11 with use of an adhesive tape. Note that the first sealing layer 12 may be stacked with use of a means other than an adhesive tape. The first sealing layer 12 in accordance with the present embodiment is made of a relatively soft resin (e.g., fluororesin such as poly tetra fluoro ethylene (PTFE) rubber, or nitrile rubber). This causes the stress acting on the first sealing layer 12 to be transmitted to the strain gauge 113 of the strain layer 11 without being absorbed by the first sealing layer 12.

A protrusion 12a is provided on an upper main surface (a main surface on a side opposite to a strain layer 11 side) of the first sealing layer 12. As illustrated at the upper left of FIG. 2, the protrusion 12a in accordance with the present embodiment is provided in a region (center part) on the upper main surface which faces the strain gauge 113 of the strain layer 11. This causes an object that is to apply stress to the first sealing layer 12 to be first brought into contact with the protrusion 12a, so that the stress from the object can be concentrated on the strain gauge 113. The protrusion 12a in accordance with the present embodiment is made of a material harder than the first sealing layer 12 (for example, an ultraviolet curing resin). This enables the stress acting on the protrusion 12a to be more directly transmitted to the strain gauge 113. Note that the protrusion 12a may be made of the same material as that of the first sealing layer 12 and be integrally formed with the first sealing layer. The protrusion 12a in accordance with the present embodiment has a hemispherical shape. This causes the protrusion 12a to be smoothly brought into contact with an object to apply stress, so that it is possible to transmit the stress from the object to the strain gauge 113 without damaging the surface of the object. Alternatively, the protrusion 12a may have a conical shape. This shape causes the protrusion 12a to be brought into contact with an object to apply stress, at an edge of the upper surface (circle) of the protrusion 12a, thereby enabling detection of fine irregularities (surface roughness).

As illustrated in FIG. 1, the first sealing layer 12 in accordance with the present embodiment is stacked so that a gap is formed between a lower main surface thereof (a main surface on a strain layer 11 side) and the strain layer 11 (strain gauge 113). This gap prevents the first sealing layer 12 on which stress has acted (which has started deformation) from being immediately brought into contact with the strain gauge 113, and the first sealing layer 12 is brought into contact with the strain gauge 113 only after the stress (deformation amount) becomes a certain value or more. That is, in the tactile sensor 1 in accordance with the present embodiment, it is possible to adjust sensitivity of the stress detection by adjusting a size of the gap. The first sealing layer 12 may be stacked so that the lower main surface thereof is brought into contact with the strain gauge 113.

### (Spacer Layer 13)

The spacer layer 13 and the strain layer 11 are stacked so that the lower main surface (the other main surface) of the strain layer 11 and the upper main surface (the other main surface) of the spacer layer 13 face each other. The spacer layer 13 in accordance with the present embodiment is bonded to the lower main surface of the strain layer 11 directly (with no other surfaces interposed therebetween) with use of an adhesive tape. Note that the spacer layer 13 may be stacked with use of a means other than an adhesive tape. The spacer layer 13 in accordance with the present embodiment is made of hard material, such as metal. This makes it possible to prevent the entire tactile sensor 1 from being deformed when stress acts on the first sealing layer 12. As illustrated at the middle right of FIG. 2, the spacer layer 13 has a ring part 13a. The structure including the ring part 13a causes a gap as illustrated in FIG. 1 to be formed between the strain element 111 (tongue part 11b) of the strain layer 11 and the second sealing layer 14 described later. The tongue part 11b can be elastically deformed by an amount corresponding to this gap. That is, adjusting the thickness of the spacer layer 13 makes it possible to adjust an upper limit of the deformation amount of the tongue part 11b.

### (Second Sealing Layer 14)

The second sealing layer 14 is stacked on the lower main surface (one main surface) of the spacer layer 13. The second sealing layer 14 seals a second space 13c (see the middle right of FIG. 2) surrounded by the ring part 13a of the spacer layer 13. The second sealing layer 14 in accordance with the present embodiment is bonded to the lower main surface of the spacer layer 13 with use of an adhesive tape. Note that the second sealing layer 14 may be stacked with use of a means other than an adhesive tape. The second sealing layer 14 is made of metal or resin.

### (Closed Space 1c)

A first space 11c inside the strain layer 11 and a second space 13c inside the spacer layer 13 communicate with each other, so that a closed space 1c is formed. The closed space 1c is partitioned by a plurality of layers (the strain layer 11, the first sealing layer 12, the spacer layer 13, and the second sealing layer 14) and is spaced from the outside of the tactile sensor 1. The closed space 1c in accordance with the present embodiment contains a gas having a pressure equal to atmospheric pressure. Note that the closed space 1c may contain a gas having a pressure higher than atmospheric pressure or a gas having a pressure than atmospheric pressure. The states in which a gas having a pressure lower than atmospheric pressure is contained include the so-called vacuum state. This makes it possible to use the tactile sensor 1 in a place having a high atmospheric pressure (for example, in a basement) or a place having a low atmospheric pressure (for example, on a mountain). Further, the closed space 1c may contain liquid. This makes it possible to use the tactile sensor 1 in water. As described above, adjusting the pressure in the closed space 1c makes it possible to use the tactile sensor 1 under various environments.

### [Effects of Tactile Sensor 1]

In the tactile sensor 1 described above, the space surrounded by the strain layer 11 and the spacer layer 13 is sealed by the first sealing layer 12 and the second sealing layer 14, so that the tongue part 11b and the strain gauge 113 (sensor part) are separated from outside air. Therefore, the tactile sensor 1 prevents water and dust from penetrating into the tactile sensor, even if the tactile sensor is used under an environment where water or dust is present in the surrounding area. This makes the sensor part free from water and dust, so that it is possible to prevent deterioration in sensitivity of stress detection of the sensor part caused by water or dust.

The tactile sensor 1 is provided with the spacer layer 13 interposed between the tongue part 11b and the second sealing layer 14 to define a range in which the tongue part 11b can be bent. Therefore, according to the tactile sensor 1, it is possible to change a rated value of the tactile sensor 1 by changing the thickness of the spacer layer 13.

Further, the sensor part having a cantilever system in which the tongue part 11b and the strain gauge 113 are integrated has a higher sensitivity of stress detection than pressure sensors and also can detect minute vibration. Therefore, according to the tactile sensor 1, it is possible to detect not only stress but also slippage (sliding against the first sealing layer 12) of an object in contact with the first sealing layer (an object gripped by a robot hand). This enables the tactile sensor 1 to be used, for example, to detect irregularities on a decorative surface and to, with reference to 3D data, check whether a target has a structure matching with the 3D data. In the sensor part having a cantilever system in which the tongue part 11b and the strain gauge 113 are integrated, the rated value can be changed also by changing at least one of the thickness and the material of the tongue part 11b. In this case, since ease of bending of the tongue part 11b is changed, not only the rated value of the sensor part but also the resolution thereof can be changed.

### <Embodiment 2 of Tactile Sensor>

Next, the following description will discuss another embodiment of the present invention. For convenience of description, a member having a function identical to that of a member discussed in the embodiment above is given an identical reference sign, and a description thereof is omitted.

### [Configuration of Tactile Sensor 1A]

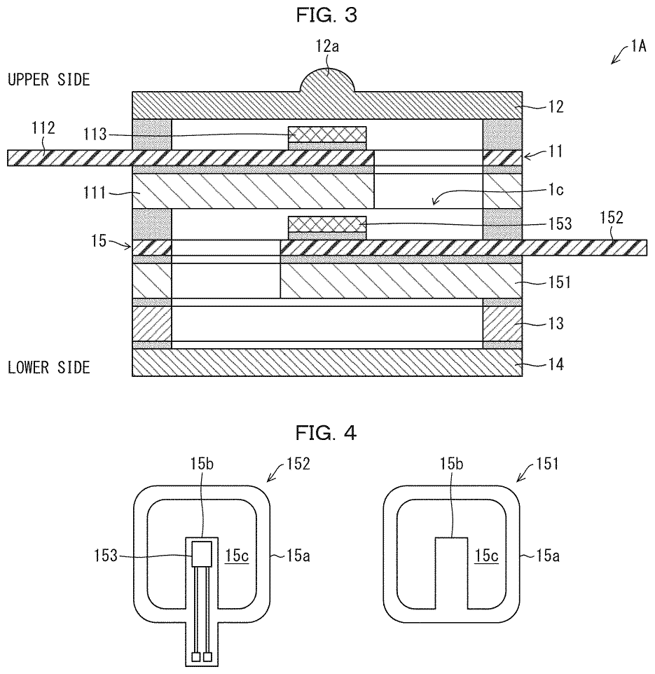

First, the following description will discuss a configuration of a tactile sensor 1A. As illustrated in FIG. 3, the tactile sensor 1A in accordance with the present embodiment further includes another strain layer 15 in addition to the strain layer 11, the first sealing layer 12, the spacer layer 13, and the second sealing layer 14 that are the same as those of the tactile sensor 1 in accordance with Embodiment 1. FIG. 3 illustrates, as an example, the tactile sensor 1A including one other strain layer 15, but the tactile sensor 1A may include a plurality of other strain layers 15. That is, the tactile sensor 1A may include three or more strain layers including the strain layer 11 and the other strain layers 15.

### (Another Strain Layer 15)

The at least one other strain layer 15 is stacked between the strain layer 11 and the spacer layer 13. The other strain layer 15 in accordance with the present embodiment is bonded to the lower main surface of the strain layer 11 with use of an adhesive tape. Note that the other strain layer 15 may be stacked with use of a means other than an adhesive tape.

The other strain layer 15 includes a strain element 151, a film substrate 152, and a strain gauge 153. As illustrated in FIG. 4, the strain element 151, the film substrate 152, and the strain gauge 153 are configured as in the case of the strain element 111, the film substrate 112, and the strain gauge 113 of the strain layer 11, respectively. Thus, the film substrate 152 is stacked on the strain element 151, so that the other strain layer 15 includes a ring part 15a and a tongue part 15b same as the ring part 11a and the tongue part 11b of the strain layer 11, respectively. Further, the other strain layer 15 is the same as the strain layer 11 also in that the strain gauge 153 is provided on the tongue part 15b.

As illustrated in FIG. 3, the other strain layer 15 in accordance with the present embodiment is stacked so that a direction in which the tongue part 15b protrudes is opposite to the direction in which the tongue part 11b of the strain layer 11 protrudes. As described above, the tongue part 11b of the strain layer 11 protrudes to a center part of the strain layer 11. Further, the other strain layer 15 is configured as in the case of the strain layer 11 (the tongue part 15b also protrudes to a center part of the other strain layer 15). Thus, the tongue part 15b of the other strain layer 15 faces the tongue part 11b of the strain layer 11. The other strain layer 15 may be stacked so that a direction in which the tongue part 15b protrudes is orthogonal to the direction in which the tongue part 11b of the strain layer 11 protrudes. The other strain layer 15 may be stacked so that the direction in which the tongue part 15b protrudes is the same as the direction in which the tongue part 11b of the strain layer 11 protrudes. In a case where a plurality of other strain layers 15 are stacked, directions in which the tongue parts 15b thereof protrude may be different from each other or may be the same.

The other strain layer 15 in accordance with the present embodiment is stacked so that a gap is formed between the strain gauge 153 and a lower surface of the strain element 111 (tongue part 11b) in the strain layer 11. This gap prevents the tongue part 11b of the strain layer 11 on which stress has acted (which has started deformation) from being immediately brought into contact with the strain gauge 153 of the other strain layer 15, and the tongue part 11b is brought into contact with the strain gauge 153 only after the stress (deformation amount) becomes a certain value or more. After the contact of the tongue part 11b with the strain gauge 153, the tongue part 15b is elastically deformed together with the tongue part 11b. That is, in the tactile sensor 1A in accordance with the present embodiment, it is possible to adjust sensitivity of the stress detection at the second stage by adjusting a size of the gap between the tongue part 11b and the strain gauge 153. In a case where a plurality of other strain layers 15 are stacked, a gap is formed also between the other strain layers 15. In this case, the tongue part 15b of the upper another strain layer 15 on which stress has acted (which has started deformation) is not immediately brought into contact with the strain gauge 153 of the lower another strain layer 15, and the tongue part 15b of the upper another strain layer 15 is brought into contact with the strain gauge 153 of the lower another strain layer 15 only after the stress becomes a certain value or more. After the contact of the tongue part 15b of the upper another strain layer 15 with the strain gauge 153 of the lower another strain layer 15, the upper tongue part 15b is elastically deformed together with the lower tongue part 15b.

### (Spacer Layer 13)

The spacer layer 13 in accordance with the present embodiment is bonded to the lower main surface of the other strain layer 15 (in a case where a plurality of other strain layers 15 are stacked, the lowest another strain layer 15) with use of an adhesive tape. That is, also in the present embodiment, the strain layer 11 and the spacer layer 13 are stacked so that the lower main surface (the other main surface) of the strain layer 11 and the upper main surface (the other main surface) of the spacer layer 13 face each other.

### (Closed Space 1c)

The first space 11c and a third space 15c surrounded by the ring part 15a of the at least one other strain layer 15 communicate with each other, and the second space 13c and the third space 15c communicate with each other, so that a closed space 1c in accordance with the present embodiment is formed. That is, the third space 15c, together with the first space 11c and the second space 13c, constitutes the closed space 1c.

### [Effects of Tactile Sensor 1A]

The tactile sensor 1A described above has similar effects to those of the tactile sensor 1 in accordance with Embodiment 1 above. Further, the tactile sensor 1A in accordance with the present embodiment includes another strain layer 15. The tactile sensor 1A in accordance with the present embodiment can be used as a multi-stage switch in which stress detection by the tongue part 11b and the strain gauge 113 (sensor part) of the strain layer 11 causes the first stage to be switched on, and stress detection by the tongue part(s) 15b and the strain gauge(s) 153 of the at least one other strain layer 15 causes the second stage, (the third stage, . . . ) to be switched on.

### <Method for Producing Tactile Sensor 1>

Next, the following description will discuss details of a method for producing the tactile sensor.

### [Flow of Method for Producing Tactile Sensor 1]

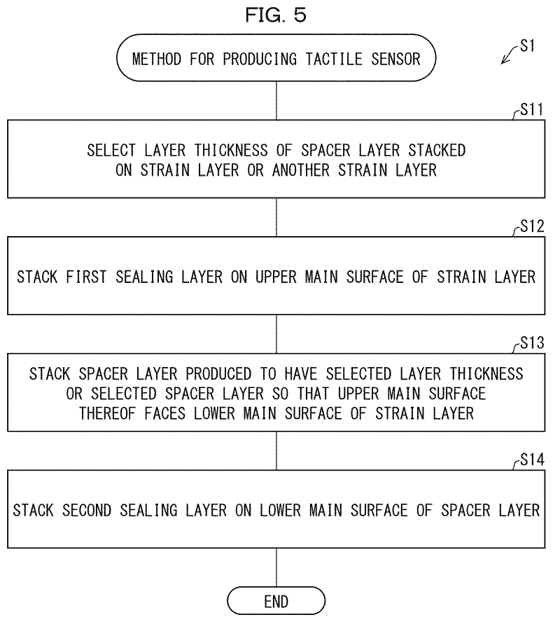

As illustrated in FIG. 5, a production method S1 for the tactile sensor 1 includes a spacer layer thickness selecting step S11, a first sealing layer stacking step S12, a spacer layer stacking step S13, and a second sealing layer stacking step S14.

### (Spacer Layer Thickness Selecting Step S11)

First, in the spacer layer thickness selecting step S11, the layer thickness of the spacer layer 13 to be stacked on the strain layer 11 or the other strain layer 15 is selected. In the selection of the layer thickness, a value of the layer thickness of the spacer layer 13 to be produced may be selected, or a spacer layer 13 having a desired layer thickness may be selected among a plurality of spacer layers 13 having different layer thicknesses. This selection determines a range in which the tongue part 11b, 15b can be elastically deformed (determines a rated value of the tactile sensor 1, 1A). Note that the layer thickness may be selected by the spacer layer stacking step S13 described later.

### (First Sealing Layer Stacking Step S12)

In the first sealing layer stacking step S12, the first sealing layer 12 is stacked on the upper main surface (one main surface) of the strain layer 11. This causes the first sealing layer 12 to seal the first space 11c surrounded by the ring part 11a of the strain layer 11.

### (Spacer Layer Stacking Step S13)

After the first sealing layer 12 has been stacked on the strain layer 11, the process proceeds to the spacer layer stacking step S13. In the spacer layer stacking step S13, the spacer layer 13 produced to have the selected layer thickness or the spacer layer 13 selected from a plurality of spacer layers 13 is stacked so that the upper main surface (the other main surface) of the spacer layer 13 is stacked so as to face the lower main surface (the other main surface) of the strain layer 11. In a case where the tactile sensor 1 is produced, the spacer layer 13 is directly stacked on the lower main surface of the strain layer 11. In a case where the tactile sensor 1A is produced, at least one other strain layer 15 is first stacked on the lower main surface of the strain layer 11, and then the spacer layer 13 is stacked on the lower main surface of the other strain layer 15. This forms the closed space 1c in which the first space 11c and the second space 13c communicate with each other. Note that the spacer layer 13 may be stacked before the first sealing layer 12 is stacked on the strain layer 11.

### (Second Sealing Layer Stacking Step S14)

After the spacer layer 13 has been stacked on the strain layer 11 or the other strain layer 15, the process proceeds to the second sealing layer stacking step S14. In the second sealing layer stacking step S14, the second sealing layer 14 is stacked on the lower main surface (one main surface) of the spacer layer 13. This causes the second sealing layer 14 to seal the second space 13c surrounded by the ring part 13a of the spacer layer 13. Further, the closed space 1c is spaced from the outside of the layers. In this way, the tactile sensor 1, 1A is produced.

### [Effects of Production Method for Tactile Sensor]

In the conventional cantilever tactile sensor, in a case where at least one of the rated value and resolution is to be changed (the cantilever tactile sensor is to be replaced with new one), it is necessary to prepare (produce) a tactile sensor having a different length or material (hardness) of a tongue part thereof from the original one. Changing the material of the tongue part is costly and needs changing a program for converting an output from the strain gauge into a stress value. Further, changing the length of the tongue part needs, depending on the rated value or the resolution to be changed, making the tongue part longer than before. The longer the tongue part is, the larger a dimension in a direction orthogonal to the direction in which the tactile sensor receives the force (a dimension in a horizontal direction) is. This may make it difficult to mount the tactile sensor to a place having a limited area, e.g., a fingertip of the robot hand. In contrast, in the production method S1 for the tactile sensor described above, the layer thickness of the spacer layer 13 stacked on the strain layer 11 or the other strain layer 15 is selected in the spacer layer thickness selecting step S11. In the spacer layer stacking step S13, the spacer layer 13 is stacked on the lower main surface of the strain layer 11 or the other strain layer 15. Therefore, according to a production method S1 for a tactile sensor, it is possible to obtain a tactile sensor having a different rated value without changing material thereof and without changing a dimension thereof in a direction orthogonal to the direction in which the force is received. In the sensor part having a cantilever system in which the tongue part 11b, 15b and the strain gauge 113, 153 are integrated, the rated value can be changed also by changing at least one of the thickness and the material of the tongue part 11b, 15b. In this case, since ease of bending of the tongue part 11b, 15b is changed, not only the rated value of the sensor part but also the resolution thereof can be changed. A configuration is also possible to select a plurality of layer thicknesses in the spacer layer thickness selecting step S11 and stack a plurality of spacer layers 13 having different thicknesses on the respective plurality of strain layers 11 in the spacer layer stacking step S13. This makes it possible to produce a tactile sensor group consisting of a collection of tactile sensors 1, 1A having rated values different from each other.

### <Additional Remark>

The present invention is not limited to the embodiments above, but can be altered by a skilled person in the art within the scope of the claims. That is, the present invention also encompasses, in its technical scope, any embodiment derived by combining technical means disclosed in differing embodiments as appropriate.

Aspects of the present invention can also be expressed as follows:

A tactile sensor in accordance with Aspect 1 of the present invention includes: a strain layer including a ring part and a tongue part protruding inward from the ring part, the tongue part being provided with a strain gauge; a first sealing layer stacked on one main surface of the strain layer so as to seal a first space surrounded by the ring part of the strain layer; a spacer layer including a ring part; and a second sealing layer stacked on one main surface of the spacer layer so as to seal a second space surrounded by the ring part of the spacer layer, the strain layer and the spacer layer being stacked so that another main surface of the strain layer and another main surface of the spacer layer face each other, and a closed space in which the first space and the second space communicate with each other is formed. According to the above configuration, the tactile sensor in accordance with Aspect 1 prevents water and dust from penetrating into the tactile sensor, even if the tactile sensor is used under an environment where water or dust is present in the surrounding area. This makes the sensor part free from water and dust, so that it is possible to prevent deterioration in sensitivity of stress detection of the sensor part caused by water or dust.

A tactile sensor in accordance with Aspect 2 of the present invention may be configured, in Aspect 1 above, such that the closed space contains a gas with a pressure higher than or lower than atmospheric pressure or liquid. A configuration in which the closed space contains a gas with a pressure higher (lower) than atmospheric pressure enables the tactile sensor to be used in a high-pressure location (low-pressure location). A configuration in which the closed space contains liquid enables the tactile sensor to be used in water.

A tactile sensor in accordance with Aspect 3 of the present invention may be configured, in Aspect 1 or 2 above, such that a protrusion is provided on a main surface that the first sealing layer has and that is located opposite the strain layer. Such a configuration causes an object that is to apply stress to the first sealing layer to be first brought into contact with the protrusion, thereby enabling the stress from the object to be concentrated on the strain gauge.

A tactile sensor in accordance with Aspect 4 of the present invention may be configured, in Aspect 3 above, such that the protrusion has a hemispherical shape or a conical shape. A configuration in which the protrusion has a hemispherical shape causes the protrusion to be smoothly brought into contact with an object to apply stress, so that it is possible to transmit the stress from the object to the strain gauge without damaging the surface of the object. A configuration in which the protrusion has a conical shape causes the protrusion to be brought into contact with an object to apply stress, at an edge of the circle of the protrusion, thereby enabling detection of fine irregularities.

A tactile sensor in accordance with Aspect 5 of the present invention may be configured, in any one of Aspects 1 to 4 above, to further include: another strain layer including a ring part and a tongue part protruding inward from the ring part, the tongue part being provided with a strain gauge, the another strain layer being stacked between the strain layer and the spacer layer so that the tongue part of the another strain layer faces the tongue part of the strain layer, and a third space surrounded by the ring part of the another strain layer, the first space, and the second space form the closed space. Such a configuration enables the tactile sensor to be used as a multi-stage switch in which stress detection by the tongue part and the strain gauge (sensor part) of the strain layer causes the first stage to be switched on, and stress detection by the tongue part(s) and the strain gauge(s) of the at least one other strain layer causes the second stage (the third stage, . . . ) to be switched on.

1. A tactile sensor comprising:
a strain layer including a ring part and a tongue part protruding inward from the ring part, the tongue part being provided with a strain gauge;
a first sealing layer stacked on one main surface of the strain layer so as to seal a first space surrounded by the ring part of the strain layer;
a spacer layer including a ring part; and
a second sealing layer stacked on one main surface of the spacer layer so as to seal a second space surrounded by the ring part of the spacer layer,
the strain layer and the spacer layer being stacked so that another main surface of the strain layer and another main surface of the spacer layer face each other, and a closed space in which the first space and the second space communicate with each other is formed.

2. The tactile sensor according to claim 1, wherein the closed space contains a gas with a pressure higher than or lower than atmospheric pressure or liquid.

3. The tactile sensor according to claim 1, wherein a protrusion is provided on a main surface that the first sealing layer has and that is located opposite to the strain layer.

4. The tactile sensor according to claim 3, wherein the protrusion has a hemispherical shape or a conical shape.

5. The tactile sensor according to claim 1, further comprising another strain layer including a ring part and a tongue part protruding inward from the ring part, the tongue part being provided with a strain gauge,
the another strain layer being stacked between the strain layer and the spacer layer so that the tongue part of the another strain layer faces the tongue part of the strain layer, and a third space surrounded by the ring part of the another strain layer, the first space, and the second space form the closed space.
